(19) United States
(12) Patent Application Publication
(10) Pub. No.: US 2025/0388418 A1
(43) Pub. Date: Dec. 25, 2025

(54) METHOD OF LOADING AND UNLOADING TRAY, TRAY LOADING AND UNLOADING APPARATUS PERFORMING THE SAME, AND ELECTRONIC DEVICE

(71) Applicant: Samsung Display Co., LTD., Yongin-si (KR)

(72) Inventors: SEOKJOO LEE, Yongin-si (KR); JUNGMIN LEE, Yongin-si (KR); WONJUN CHOI, Yongin-si (KR)

(21) Appl. No.: 19/225,898

(22) Filed: Jun. 2, 2025

(30) Foreign Application Priority Data
Jun. 19, 2024 (KR) 10-2024-0079338

(51) Int. Cl. B65G 65/02; B65G 47/90; B65G 65/23

(52) U.S. Cl. CPC B65G 65/02; B65G 47/907; B65G 65/23; B65G 2201/0258

(57) ABSTRACT

A method of loading and unloading a tray includes: transporting trays, on which a panel is disposed; gripping a first tray among the trays and loading the first tray on a first plate; gripping the first tray loaded on the first plate and loading the first tray on a second plate spaced apart from the first plate, while simultaneously gripping a second tray different from the first tray among the trays; extracting the panel from the first tray loaded on the second plate; and recovering empty trays, from which the panel is extracted.

This application claims priority to Korean Patent Application No. 10-2024-0079338, filed on Jun. 19, 2024, and all the benefits accruing therefrom under 35 U.S.C. § 119, the content of which in its entirety is herein incorporated by reference.

### BACKGROUND

### 1. Field

The disclosure relates generally to a method of loading and unloading a tray. More particularly, the disclosure relates to a method of loading and unloading a tray and a tray loading and unloading apparatus performing the method.

### 2. Description of the Related Art

In general, an electronic component may be placed on a tray to prevent damage as the electronic component is put into a work process. For example, the electronic component may be a display panel, a printed circuit board, a battery module, or the like. In addition, a plurality of trays on which the electronic component is placed may be stacked and may be put into a work process for transportation efficiency.

A tray loading and unloading apparatus may supply the electronic component from the plurality of trays on which the electronic component is placed. When the electronic component is extracted by an external apparatus, the tray loading and unloading apparatus may discharge an empty tray from which the electronic component is extracted. Recently, research has been conducted to reduce a process time (or, a working time) using the tray loading and unloading apparatus.

### SUMMARY

Embodiments provide a method of loading and unloading a tray with a reduced process time.

Embodiments provide a tray loading and unloading apparatus performing the method of loading and unloading the tray.

Embodiments provide an electronic device including a display panel loaded by the tray loading and unloading apparatus.

A method of loading and unloading a tray according to an embodiment of the disclosure includes: transporting trays, on which a panel is disposed; gripping a first tray among the trays and loading the first tray on a first plate; gripping the first tray loaded on the first plate and loading the first tray on a second plate spaced apart from the first plate, while simultaneously gripping a second tray different from the first tray among the trays; extracting the panel from the first tray loaded on the second plate; and recovering empty trays, from which the panel is extracted.

In an embodiment, the method may further include loading the second tray on the second plater after the extracting the panel from the first tray and extracting the panel from the second tray loaded on the second plate.

In an embodiment, the first tray may be loaded on the second plate by a first gripper, and the second tray may be loaded on the second plate by a second gripper different from the first gripper.

In an embodiment, the first gripper and the second gripper may alternately load the trays on the second plate.

In an embodiment, the method may further include loading at least one of the trays on a buffer member after the transporting the trays.

In an embodiment, a tray located at a bottommost position among the trays may be loaded on the buffer member.

In an embodiment, the transporting the trays may include loading the trays may on a lifting and lowering member and raising the trays by the lifting and lowering member.

In an embodiment, the buffer member may receive the at least one of the trays from the lifting and lowering member.

In an embodiment, the method may further include lowering the lifting and lowering member after the loading the at least one of the trays on the buffer member.

A tray loading and unloading apparatus according to an embodiment of the disclosure includes: a tray input part which transports trays on which a panel is disposed from a first area to a second area adjacent to the first area in a first direction; a first tray lifting and lowering part overlapping the second area, where the first tray lifting and lower part raises the trays transported by the tray input part; a tray shuttle part which grips each of the trays from the first tray lifting and lowering part, which loads each of the trays on a shuttle plate, and transports the shuttle plate in a second direction intersecting the first direction; an auxiliary tray shuttle part which grips each of the trays loaded on the shuttle plate and loads each of the trays on an auxiliary plate spaced apart from the shuttle plate; a second tray lifting and lowering part overlapping a third area adjacent to the second area in the second direction, wherein the second tray lifting and lowering part lowers an empty tray from which the panel is extracted; and a tray discharge part which transports the empty tray from the third area to an outside of the apparatus.

In an embodiment, the panel may be extracted while being loaded on the auxiliary plate.

In an embodiment, the auxiliary tray shuttle part may include an auxiliary gripper which grips each of the trays loaded on the shuttle plate and an auxiliary gripper driver which transports the auxiliary gripper toward the auxiliary plate.

In an embodiment, the auxiliary gripper may include a first auxiliary gripper and a second auxiliary gripper which are driven independently of each other. In such an embodiment, the auxiliary gripper driver may include a first auxiliary gripper driver which transports the first auxiliary gripper and a second auxiliary gripper driver which transports the second auxiliary gripper.

In an embodiment, when the first auxiliary gripper overlaps the auxiliary plate in a plan view, the second auxiliary gripper may be spaced apart from the auxiliary plate in the plan view.

In an embodiment, the first auxiliary gripper and the second auxiliary gripper may alternately load the trays on the auxiliary plate.

In an embodiment, the apparatus may further include a tray buffer part on which at least one of the trays are loaded.

In an embodiment, the tray buffer part may receive the at least one of the trays from the first tray lifting and lowering part.

In an embodiment, the tray buffer part may include buffer support parts which contact the at least one of the trays.

In an embodiment, the buffer support parts may include first buffer support parts disposed in the second area and second buffer support parts disposed in the third area.

An electronic device according to an embodiment of the disclosure includes: a display device including a display panel loaded by a tray loading and unloading apparatus; and a processor which transmits an image data signal and an input control signal to the display device. The tray loading and unloading apparatus includes: a tray input part which transports trays on which the display panel is disposed from a first area to a second area adjacent to the first area in a first direction; a first tray lifting and lowering part overlapping the second area, where the first tray lifting and lower part raises the trays transported by the tray input part; a tray shuttle part which grips each of the trays from the first tray lifting and lowering part, which loads each of the trays on a shuttle plate, and transports the shuttle plate in a second direction intersecting the first direction; an auxiliary tray shuttle part which grips each of the trays loaded on the shuttle plate and loads each of the trays on an auxiliary plate spaced apart from the shuttle plate; a second tray lifting and lowering part overlapping a third area adjacent to the second area in the second direction, wherein the second tray lifting and lowering part lowers an empty tray from which the display panel is extracted; and a tray discharge part which transports the empty tray from the third area to an outside of the apparatus.

A method of loading and unloading a tray according to an embodiment of the disclosure may include gripping a first tray among a plurality of trays and loading the first tray on a first plate, gripping the first tray loaded on the first plate and loading the first tray on a second plate spaced apart from the first plate, while simultaneously gripping a second tray different from the first tray among the trays, and extracting a panel from the first tray loaded on the second plate.

In such an embodiment, while the first tray is gripped and loaded on the second plate, a tray from which the panel is to be extracted in the next process may be gripped. That is, while the first tray is gripped and loaded on the second plate, a second tray from which the panel is to be extracted in the next process may be gripped. Accordingly, since the second tray from which the panel is to be extracted in the next process can be prepared in advance, the process time can be reduced compared to a case where the panel is extracted while being loaded on the first plate.

### BRIEF DESCRIPTION OF THE DRAWINGS

Illustrative, non-limiting embodiments will be more clearly understood from the following detailed description in conjunction with the accompanying drawings.

FIG. 1 is a perspective view illustrating a tray loading and unloading apparatus according to an embodiment of the disclosure.

FIG. 2 is a side view illustrating the tray loading and unloading apparatus of FIG. 1.

FIG. 3 is a front view illustrating the tray loading and unloading apparatus of FIG. 1.

FIG. 4 is a perspective view illustrating a tray input part and a tray discharge part included in the tray loading and unloading apparatus of FIG. 1.

FIG. 5 is a plan view illustrating the tray input part and the tray discharge part of FIG. 4.

FIG. 6 is a perspective view illustrating tray lifting and lowering parts included in the tray loading and unloading apparatus of FIG. 1.

FIG. 7 is a perspective view illustrating a tray shuttle part included in the tray loading and unloading apparatus of FIG. 1.

FIG. 8 is a flowchart illustrating a method of loading and unloading a tray according to an embodiment of the disclosure.

FIGS. 9 to 21 are views illustrating an embodiment of the method of loading and unloading the tray of FIG. 8.

FIGS. 22 and 23 are views illustrating a method of loading and unloading a tray according to an embodiment of the disclosure.

FIG. 24 is a block diagram of an electronic device according to an embodiment of the present disclosure.

FIG. 25 is a schematic diagram of an electronic device according to various embodiments.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the disclosure will be described in detail with reference to the accompanying drawings. The same reference numerals are used for the same components in the drawings, and any repetitive detailed descriptions of the same components will be omitted.

In this specification, a plane may be defined by a first direction DR1 and a second direction DR2 intersecting the first direction DR1. For example, the first direction DR1 and the second direction DR2 may be perpendicular to each other. A direction normal to the plane may be a third direction DR3. In other words, the third direction DR3 may be perpendicular to each of the first direction DR1 and the second direction DR2. As used herein the “plan view” is a view in the third direction DR3. As used herein the “front view” is a view in the first direction DR1. As used herein the “side view” is a view in the second direction DR2.

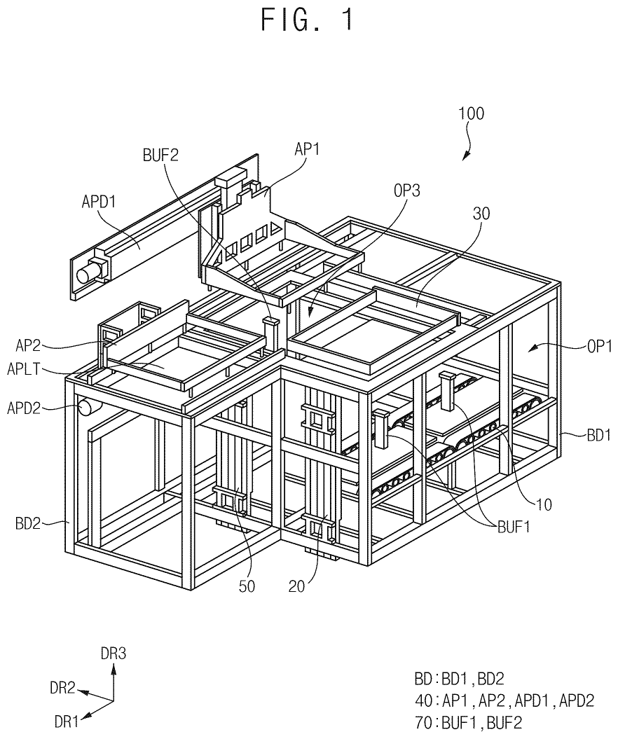

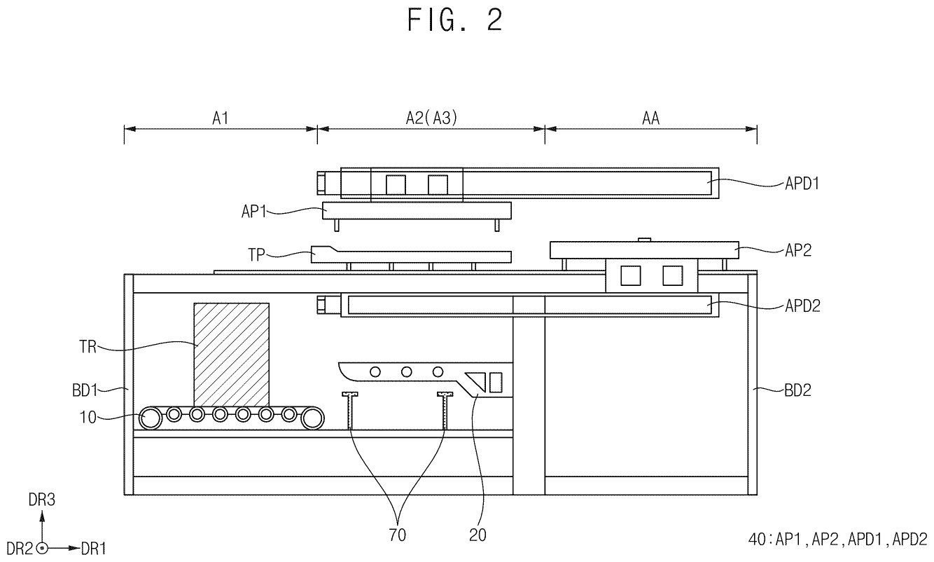

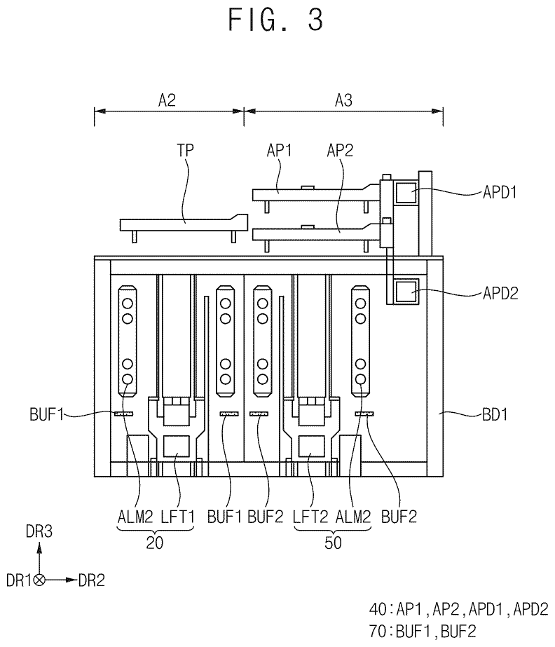

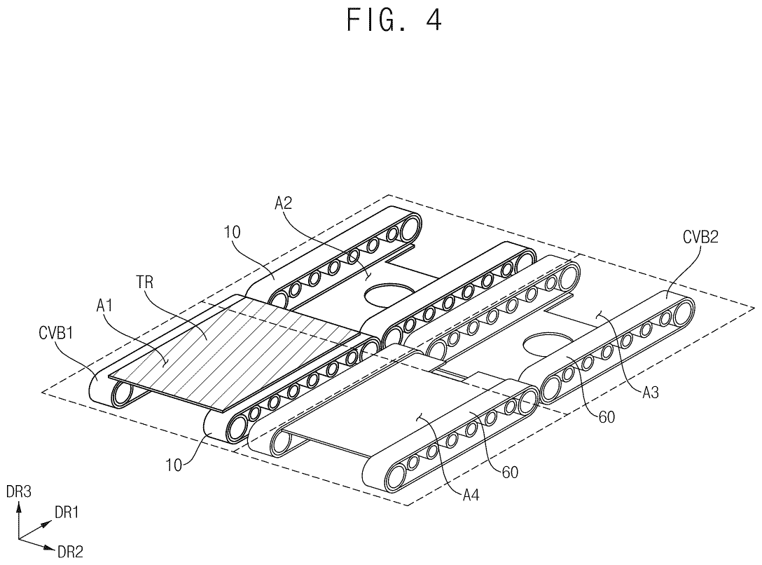

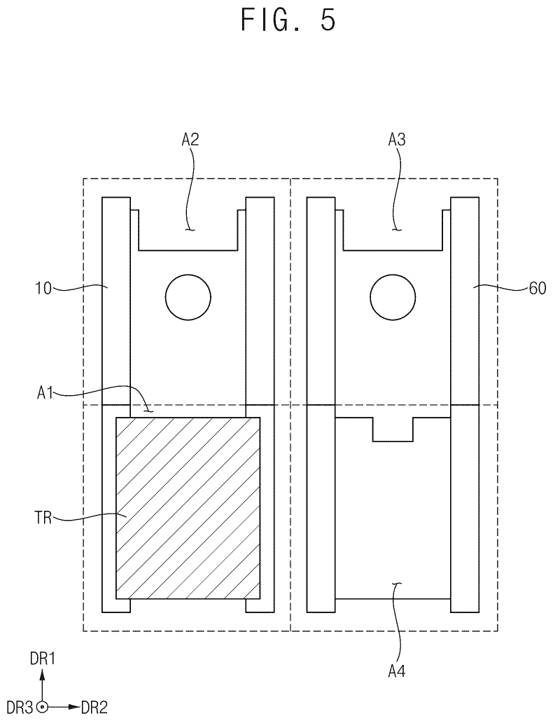

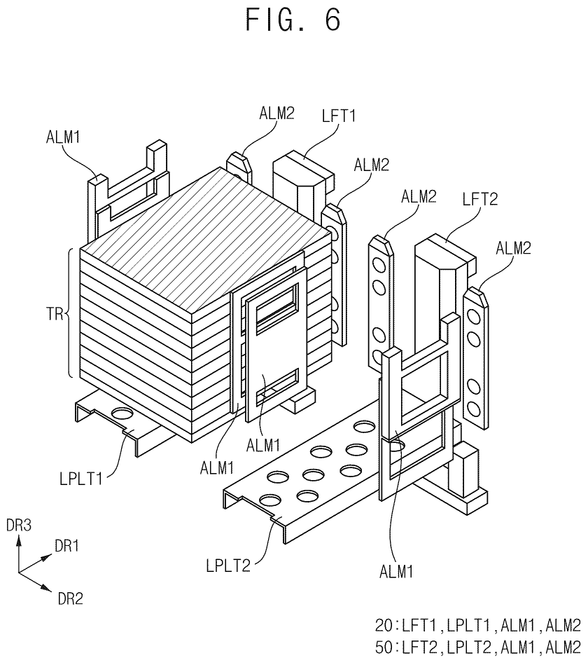

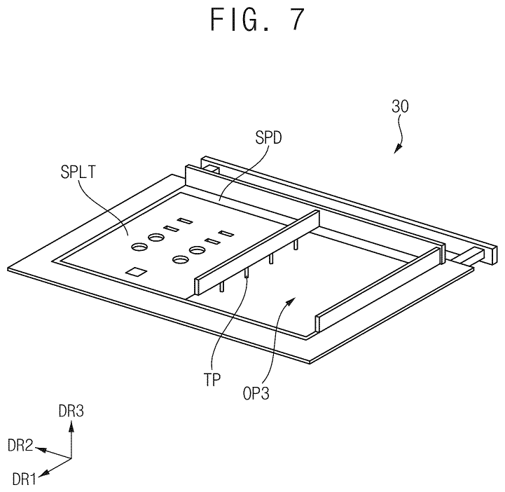

FIG. 1 is a perspective view illustrating a tray loading and unloading apparatus according to an embodiment of the disclosure. FIG. 2 is a side view illustrating the tray loading and unloading apparatus of FIG. 1. Particularly, FIG. 2 is a side view of the tray loading and unloading apparatus of FIG. 1 as viewed in the second direction DR2. FIG. 3 is a front view illustrating the tray loading and unloading apparatus of FIG. 1. Particularly, FIG. 3 is a front view of the tray loading and unloading apparatus of FIG. 1 as viewed in the first direction DR1. FIG. 4 is a perspective view illustrating a tray input part and a tray discharge part included in the tray loading and unloading apparatus of FIG. 1. FIG. 5 is a plan view illustrating the tray input part and the tray discharge part of FIG. 4. FIG. 6 is a perspective view illustrating tray lifting and lowering parts included in the tray loading and unloading apparatus of FIG. 1. FIG. 7 is a perspective view illustrating a tray shuttle part included in the tray loading and unloading apparatus of FIG. 1.

Referring to FIGS. 1, 2, 3, 4, 5, 6, and 7, a tray loading and unloading apparatus 100 according to an embodiment of the disclosure may include a body part BD, a tray input part 10, a first tray lifting and lowering part 20, a tray shuttle part 30, an auxiliary tray shuttle part 40, an auxiliary plate APLT, a second tray lifting and lowering part 50, a tray discharge part 60, and a tray buffer part 70.

The tray loading and unloading apparatus 100 may supply a plurality of trays TR on which a panel is disposed (or loaded). When the panel is extracted (or unloaded) from the trays by an external apparatus (e.g., a transfer arm), the tray loading and unloading apparatus 100 may discharge empty trays (e.g., an empty tray ETR of FIG. 19) from which the panel is extracted.

In an embodiment, the panel may be a display panel included in a display device that displays an image. However, the present disclosure is not limited thereto, and the tray loading and unloading apparatus 100 may supply a plurality of trays TR on which an electronic component such as a printed circuit board, a battery module, etc. is loaded.

The body part BD may include a skeleton (or a basic frame) of the tray loading and unloading apparatus 100. The body part BD may include a first body part BD1 and a second body part BD2.

A first gate OP1 and a second gate may be defined or formed on a side surface of the first body part BD1. The first gate OP1 and the second gate may serve as a passage through which the trays TR move between an inside of the first body part BD1 and an outside of the first body part BD1. In an embodiment, for example, the first gate OP1 may serve as a passage through which the trays TR on which the panel is disposed move from the outside of the first body part BD1 to the inside of the first body part BD1. The second gate may serve as a passage through which the empty trays from which the panel is extracted move from the inside of the first body part BD1 to the outside of the first body part BD1. Although not illustrated in FIG. 1, the first gate OP1 and the second gate may be adjacent to each other in the second direction DR2.

A third gate OP3 may be defined or formed on an upper surface of the first body part BD1. The third gate OP3 may serve as a passage through which the trays TR move between the inside of the first body part BD1 and an upper portion of the first body part BD1. In an embodiment, for example, the third gate OP3 may serve as a passage through which the trays TR on which the panel is disposed move from the inside of the first body part BD1 to the upper portion of the first body part BD1. In addition, the third gate OP3 may serve as a passage through which the empty trays from which the panel is extracted move from the upper portion of the first body part BD1 to the inside of the first body part BD1.

The first body part BD1 may include a first area A1, a second area A2, a third area A3, and a fourth area A4.

The first area A1 may be defined as an area where the trays TR input through the first gate OP1 are loaded on a first conveyor belt (CVB1, refer to FIG. 4).

The second area A2 may be defined as an area where the trays TR transported by the first conveyor belt CVB1 are raised by the first tray lifting and lowering part (20, refer to FIG. 3). The second area A2 may be adjacent to the first area A1 in the first direction DR1.

The third area A3 may be defined as an area where the empty trays from which the panel is extracted are lowered by the second tray lifting and lowering part (50, refer to FIG. 3). The third area A3 may be adjacent to the second area A2 in the second direction DR2.

The fourth area A4 may be defined as an area where the empty trays are transported by a second conveyor belt (CVB2, refer to FIG. 4), and where the empty trays are discharged to the outside of the first body part BD1 through the second gate. The fourth area A4 may be adjacent to the third area A3 in the first direction DR1. In addition, the fourth area A4 may be adjacent to the first area A1 in the second direction DR2.

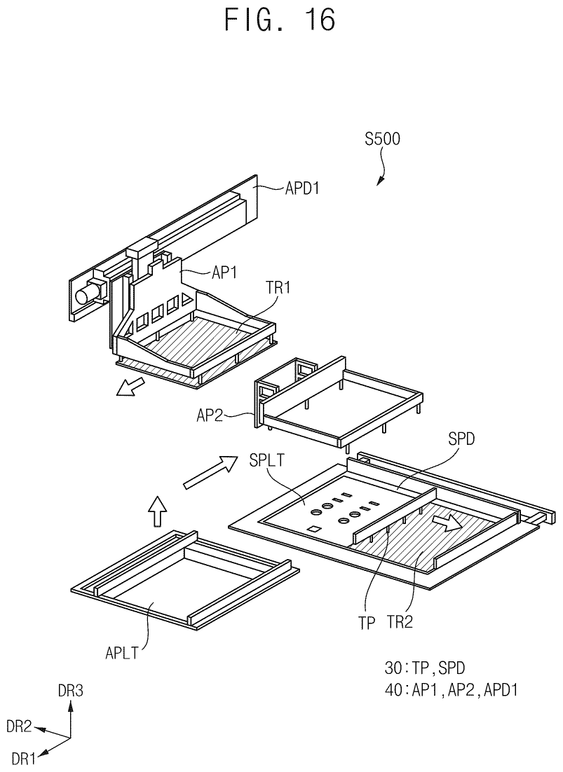

The second body part BD2 may be connected to the first body part BD1. The second body part BD2 may include an auxiliary area AA. The auxiliary area AA may be defined as an area where the auxiliary plate APLT is disposed. In other words, the auxiliary plate APLT may be disposed in the auxiliary area AA on the second body part BD2. The tray TR held by the auxiliary tray shuttle part 40 may be loaded on the auxiliary plate APLT. A detailed features thereof will be described below with reference to FIGS. 15, 16, and 17. In an embodiment, the auxiliary area AA may be adjacent to the third area A3 in the first direction DR1.

The tray input part 10 may be disposed inside the first body part BD1 in the first area A1 and the second area A2. The tray input part 10 may transport the trays TR input through the first gate OP1 in the first direction DR1. In an embodiment, as illustrated in FIGS. 4 and 5, the tray input part 10 may include the first conveyor belt CVB1, and the first conveyor belt CVB1 may move in the first direction DR1. The trays TR may be loaded on the first conveyor belt CVB1. Accordingly, the first conveyor belt CVB1 may transport the trays TR in the first direction DR1.

The tray input part 10 may transport the trays TR from the first area A1 to the second area A2. In an embodiment, the first conveyor belt CVB1 may transport the trays TR from the first area A1 to the second area A2. The first conveyor belt CVB1 may be disposed inside the first body part BD1 in the first area A1. In addition, although not illustrated in FIG. 2, the first conveyor belt CVB1 may be disposed inside the first body part BD1 in the second area A2.

The first tray lifting and lowering part 20 may be disposed inside the first body part BD1 in the second area A2. That is, the first tray lifting and lowering part 20 may overlap the second area A2. The first tray lifting and lowering part 20 may raise the trays TR transported by the tray input part 10.

In an embodiment, as illustrated in FIGS. 3 and 6, the first tray lifting and lowering part 20 may include a first tray lifter LFT1, a first lifter plate LPLT1, first alignment members ALM1, and second alignment members ALM2.

The trays TR transported by the tray input part 10 may be loaded on the first lifter plate LPLT1. In other words, the first lifter plate LPLT1 may support the trays TR transported by the tray input part 10.

The first alignment members ALM1 and the second alignment members ALM2 may align the trays TR loaded on the first lifter plate LPLT1. In an embodiment, the first alignment members ALM1 may align the loaded trays TR in a width direction (e.g., the second direction DR2). The second alignment members ALM2 may align the loaded trays TR in a length direction (e.g., the first direction DR1).

The first tray lifter LFT1 may raise or lower the first lifter plate LPLT1. Accordingly, the first tray lifter LFT1 may raise the trays TR loaded on the first lifter plate LPLT1 toward the upper portion of the first body part BD1. In other words, the first tray lifter LFT1 may transport the trays TR in the third direction DR3.

The tray shuttle part 30 may be disposed on the upper portion of the first body part BD1. The tray shuttle part 30 may grip each of the trays TR from the first tray lifting and lowering part 20 and may transport the trays TR in the second direction DR2.

In an embodiment, as illustrated in FIGS. 1, 2, and 7, the tray shuttle part 30 may include a tray gripper TP and a shuttle plate driver SPD.

The tray gripper TP may sequentially grip each of the trays TR raised by the first tray lifting and lowering part 20 and may load the tray TR on a shuttle plate SPLT. That is, the tray gripper TP may grip each tray TR one by one and may load each tray TR on the shuttle plate SPLT. In other words, the tray gripper TP may sequentially grip a tray located at the uppermost position among the trays TR. In an embodiment, for example, the tray gripper TP may grip the tray TR by vacuum suction.

The shuttle plate driver SPD may move the shuttle plate SPLT in the second direction DR2 or in the opposite direction of the second direction DR2. Accordingly, the shuttle plate driver SPD may move the tray TR loaded on the shuttle plate SPLT in the second direction DR2.

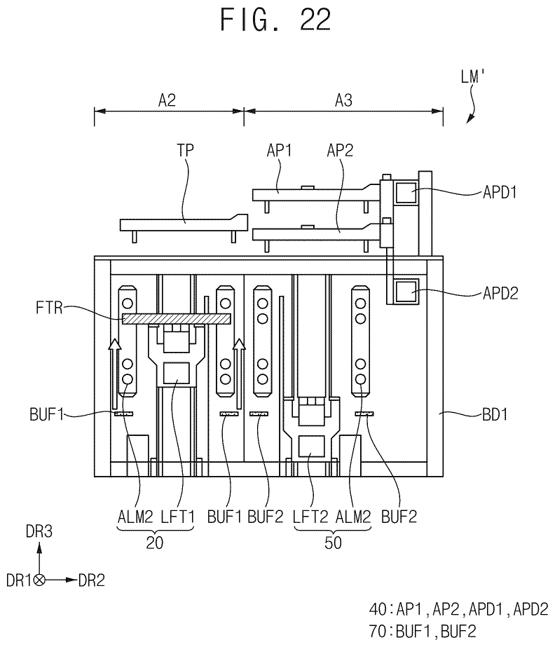

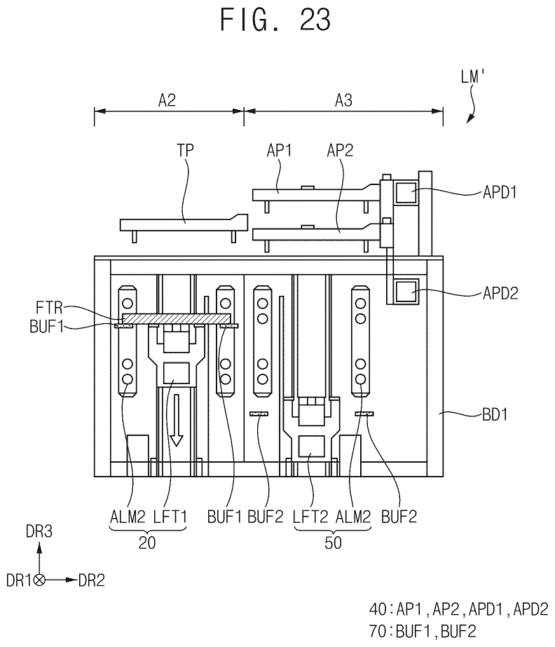

The tray buffer part 70 may be disposed inside the first body part BD1 in the second area A2. The tray buffer part 70 may receive some of the trays TR from the first tray lifting and lowering part 20. The tray buffer part 70 may support some of the trays TR before being gripped by the tray shuttle part 30. The tray buffer part 70 may include a plurality of first buffer support parts BUF1 that support some of the trays TR. A detailed features thereof will be described below with reference to FIGS. 22 and 23.

The auxiliary tray shuttle part 40 may be disposed on the upper portion of the first body part BD1. The auxiliary tray shuttle part 40 may grip the tray TR loaded on the shuttle plate SPLT and may load the tray TR on the auxiliary plate APLT. The auxiliary plate APLT may be spaced apart from the shuttle plate SPLT.

In an embodiment, as illustrated in FIGS. 1, 2, and 3, the auxiliary tray shuttle part 40 may include a first auxiliary gripper AP1, a second auxiliary gripper AP2, a first auxiliary gripper driver APD1, and a second auxiliary gripper driver APD2.

Each of the first auxiliary gripper AP1 and the second auxiliary gripper AP2 may be raised or lowered. Each of the first auxiliary gripper AP1 and the second auxiliary gripper AP2 may descend to grip one tray TR loaded on the shuttle plate SPLT and then rise. In an embodiment, for example, each of the first auxiliary gripper AP1 and the second auxiliary gripper AP2 may grip the tray TR by vacuum suction. The first auxiliary gripper AP1 and the second auxiliary gripper AP2 may be driven independently of each other.

The first auxiliary gripper driver APD1 may transport the first auxiliary gripper AP1. In an embodiment, for example, the first auxiliary gripper driver APD1 may transport the first auxiliary gripper AP1 in the first direction DR1 or in the opposite direction of the first direction DR1. Accordingly, the first auxiliary gripper driver APD1 may transport the first auxiliary gripper AP1 in the first direction DR1 such that the first auxiliary gripper AP1 overlaps the auxiliary plate APLT in a plan view. The first auxiliary gripper AP1 may descend in an area overlapping the auxiliary plate APLT in a plan view and may load the tray TR on the auxiliary plate APLT.

In such an embodiment, the second auxiliary gripper driver APD2 may transport the second auxiliary gripper AP2. In an embodiment, for example, the second auxiliary gripper driver APD2 may transport the second auxiliary gripper AP2 in the first direction DR1 or in the opposite direction of the first direction DR1. Accordingly, the second auxiliary gripper driver APD2 may transport the second auxiliary gripper AP2 in the first direction DR1 such that the second auxiliary gripper AP2 overlaps the auxiliary plate APLT in a plan view. The second auxiliary gripper AP2 may descend in the area overlapping the auxiliary plate APLT in a plan view and may load the tray TR on the auxiliary plate APLT.

In embodiments, when the first auxiliary gripper AP1 overlaps the auxiliary plate APLT in a plan view, the second auxiliary gripper AP2 may be spaced apart from the auxiliary plate APLT in a plan view. In other words, when the first auxiliary gripper AP1 overlaps the auxiliary area AA, the second auxiliary gripper AP2 may be spaced apart from the auxiliary area AA.

In embodiments, the first auxiliary gripper AP1 and the second auxiliary gripper AP2 may alternately load the tray TR on the auxiliary plate APLT. In an embodiment, for example, when the first auxiliary gripper AP1 loads a tray which is located at (N−1)-th position from the top among the trays TR on the auxiliary plate APLT, the second auxiliary gripper AP2 may load a tray which is located at N-th position from the top among the trays TR on the auxiliary plate APLT. In this case, N is a natural number greater than 1. A detailed features thereof will be described below with reference to FIGS. 15, 16, and 17.

The panel of the tray TR loaded on the auxiliary plate APLT may be extracted by the external apparatus. In an embodiment, the auxiliary tray shuttle part 40 may deliver the empty tray from which the panel is extracted to the second tray lifting and lowering part 50. In an embodiment, the auxiliary tray shuttle part 40 may deliver the empty tray from which the panel is extracted to the tray shuttle part 30.

The second tray lifting and lowering part 50 may be disposed inside the first body part BD1 in the third area A3. That is, the second tray lifting and lowering part 50 may overlap the third area A3. The second tray lifting and lowering part 50 may lower the empty trays from which the panel is extracted.

In an embodiment, as illustrated in FIGS. 3 and 6, the second tray lifting and lowering part 50 may include a second tray lifter LFT2, a second lifter plate LPLT2, the first alignment members ALM1 and the second alignment members ALM2.

The empty trays from which the panel is extracted may be loaded on the second lifter plate LPLT2. In other words, the second lifter plate LPLT2 may support the empty trays.

The first alignment members ALM1 and the second alignment members ALM2 may align the empty trays loaded on the second lifter plate LPLT2. In an embodiment, the first alignment members ALM1 may align the loaded empty trays in the width direction (e.g., the second direction DR2). The second alignment members ALM2 may align the loaded empty trays in the length direction (e.g., the first direction DR1).

The second tray lifter LFT2 may raise or lower the second lifter plate LPLT2. Accordingly, the second tray lifter LFT2 may lower the empty trays loaded on the second lifter plate LPLT2. In other words, the second tray lifter LFT2 may transport the empty trays in the opposite direction of the third direction DR3.

In an embodiment, as illustrated in FIG. 3, the tray buffer part 70 may be further disposed inside the first body part BD1 in the third area A3. The tray buffer part 70 may receive some of the empty trays from the auxiliary tray shuttle part 40 or the tray shuttle part 30. In other words, the tray buffer part 70 may support some of the empty trays before being delivered to the second tray lifting and lowering part 50. The tray buffer part 70 may include a plurality of second buffer support parts BUF2 that support some of the empty trays. A detailed features thereof will be described below with reference to FIGS. 22 and 23.

The tray discharge part (60, refer to FIG. 4) may be disposed inside the first body part BD1 in the third area A3 and the fourth area A4. The tray discharge part 60 may transport the empty trays in the opposite direction of the first direction DR1. In an embodiment, as illustrated in FIGS. 4 and 5, the tray discharge part 60 may include a second conveyor belt CVB2, and the second conveyor belt CVB2 may move in the opposite direction of the first direction DR1. The empty trays may be loaded on the second conveyor belt CVB2. Accordingly, the second conveyor belt CVB2 may transport the empty trays in the opposite direction of the first direction DR1.

The tray discharge part 60 may transport the empty trays from the third area A3 to the fourth area A4. In an embodiment, the second conveyor belt CVB2 may transport the empty trays from the third area A3 to the fourth area A4. In addition, the empty trays from which the panel is extracted may be transported to an outside of the tray loading and unloading apparatus 100 by the second conveyor belt CVB2. In other words, the empty trays from which the panel is extracted may be discharged to the outside of the tray loading and unloading apparatus 100 by the second conveyor belt CVB2.

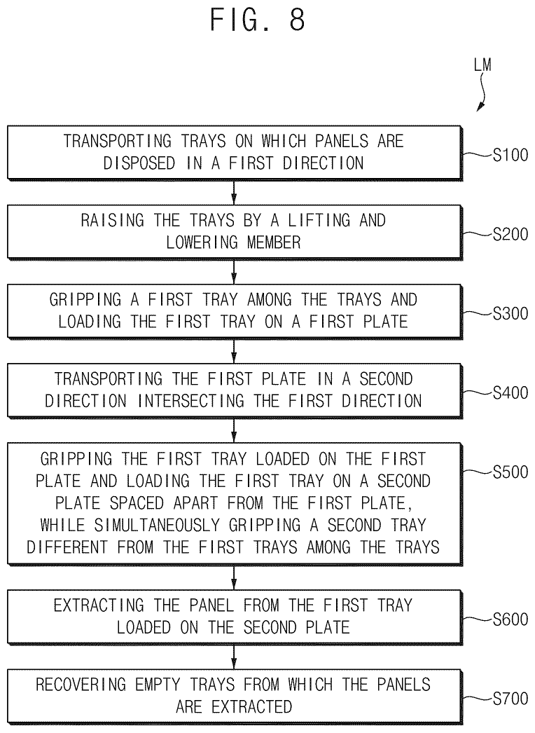

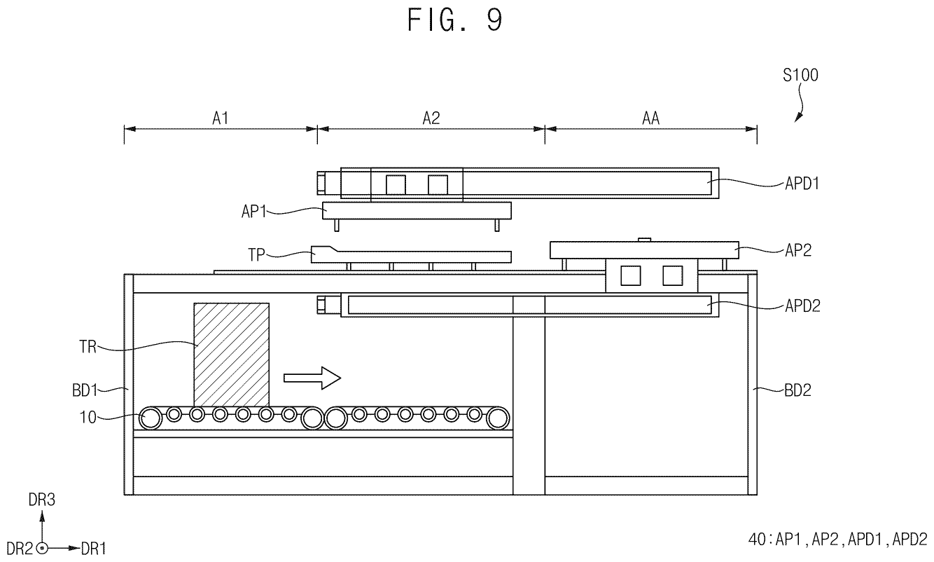

FIG. 8 is a flowchart illustrating a method of loading and unloading a tray according to an embodiment of the disclosure. FIGS. 9 to 21 are views illustrating an embodiment of the method of loading and unloading the tray of FIG. 8.

For example, an embodiment of a method LM of loading and unloading a tray described below with reference to FIGS. 9 to 21 may be performed using the tray loading and unloading apparatus 100 described above with reference to FIGS. 1 to 7. Hereinafter, any repetitive detailed descriptions of the same or like elements as those of the tray loading and unloading apparatus 100 described above with reference to FIGS. 1 to 7 may be omitted or simplified.

Referring to FIG. 8, the method LM of loading and unloading the tray according to an embodiment of the disclosure may include transporting trays, on which panel is disposed, in a first direction (S100), raising the trays by a lifting and lowering member (S200), gripping a first tray among the trays and loading the first tray on a first plate (S300), transporting the first plate in a second direction intersecting the first direction (S400), gripping the first tray loaded on the first plate and loading the first tray on a second plate spaced apart from the first plate, while simultaneously gripping a second tray different from the first tray among the trays (S500), extracting the panels from the first tray loaded on the second plate (S600), and recovering empty trays form which the panel is extracted (S700).

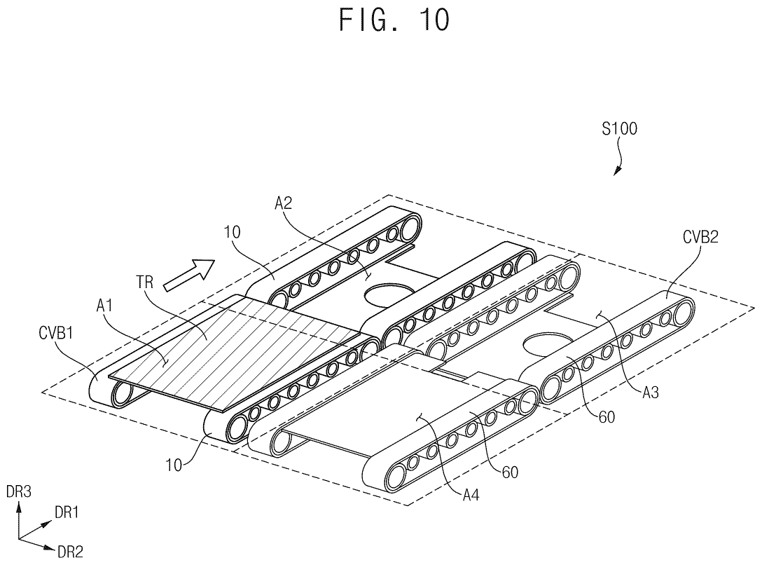

Referring to FIGS. 9 and 10, the plurality of trays TR, on which the panel is disposed, may be transported in the first direction DR1 (S100).

The trays TR on which the panel is disposed may move inside the first body part BD1 through the first gate (OP1, refer to FIG. 1) of the first body part BD1. The tray input part 10 may transport the trays TR in the first direction DR1. In an embodiment, the trays TR may be loaded on the first conveyor belt CVB1, and the first conveyor belt CVB1 may transport the trays TR from the first area A1 to the second area A2.

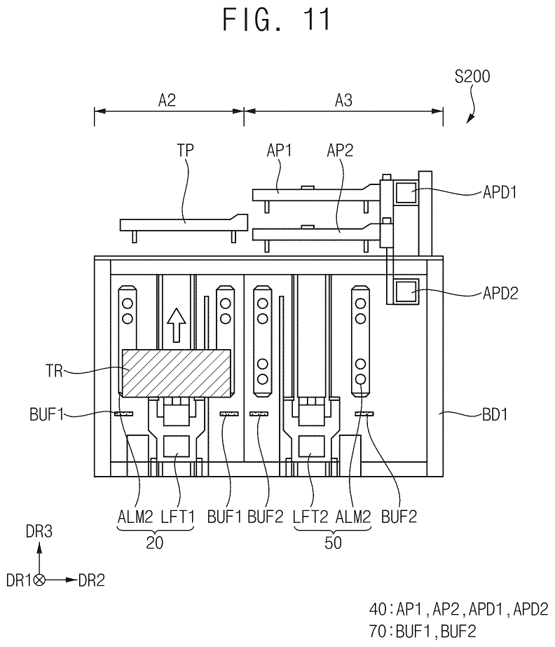

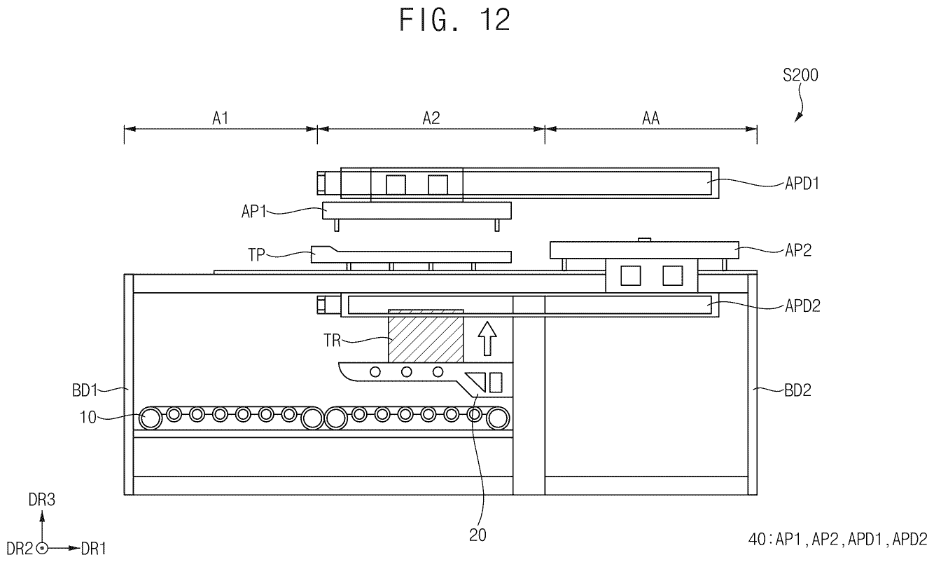

Referring to FIGS. 11 and 12, the trays TR may be raised by the lifting and lowering member (S200). In an embodiment, the trays TR transported by the tray input part 10 may be raised by the first tray lifting and lowering part 20.

The trays TR transported by the tray input part 10 may be loaded on the first lifter plate (LPLT1, refer to FIG. 6). After the trays TR are loaded on the first lifter plate, the first alignment members (ALM1, refer to FIG. 6) and the second alignment members ALM2 may align the trays TR. The first tray lifter LFT1 may raise the trays TR loaded on the first lifter plate toward the upper portion of the first body part BD1. In other words, the first tray lifter LFT1 may transport the trays TR in the third direction DR3.

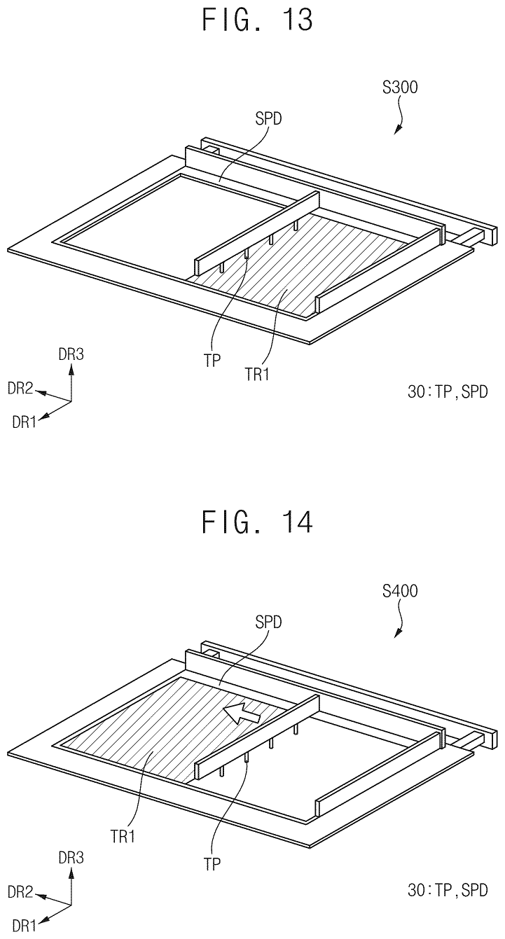

Referring to FIG. 13, a first tray TR1 among the trays TR may be gripped and may be loaded on a first plate (S300). In an embodiment, the first tray TR1 may be gripped by the tray gripper TP and may be loaded on the shuttle plate (SPLT, refer to FIG. 7).

The tray gripper TP may sequentially grip each of the trays TR raised by the first tray lifting and lowering part 20. In other words, the tray gripper part TP may sequentially grip a tray located at the uppermost position among the trays TR. In an embodiment, for example, the tray gripper TP may grip the first tray TR1 first. The first tray TR1 may be defined as a tray located at the uppermost position among the trays TR raised by the first tray lifting and lowering part 20.

The tray gripper TP may grip the first tray TR1 through the third gate (OP3, refer to FIG. 7) of the first body part BD1. The tray gripper TP may descend to grip the first tray TR1 and then rise.

To load the first tray TR1 on the shuttle plate, the shuttle plate driver SPD may transport the shuttle plate located in the third area (A3, refer to FIG. 11) to the second area (A2, refer to FIG. 11). In other words, the shuttle plate driver SPD may transport the shuttle plate in the opposite direction of the second direction DR2. When the shuttle plate is located in the second area, the tray gripper TP may load the first tray TR1 on the shuttle plate.

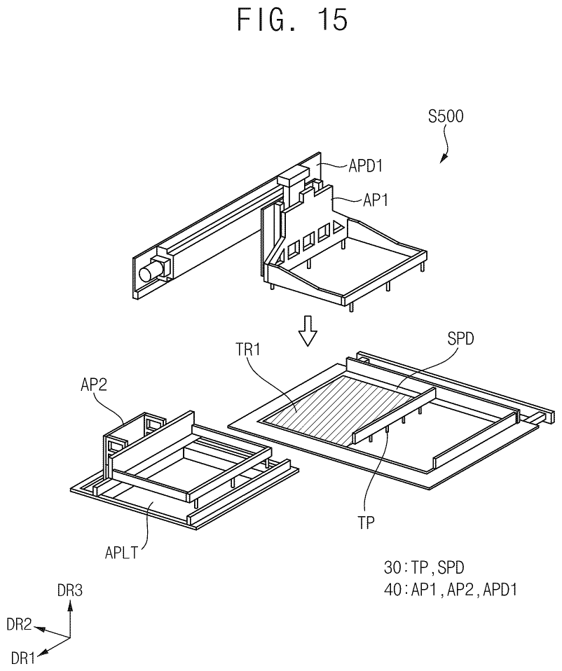

Referring to FIG. 14, the first plate may move in the second direction DR2 (S400). In an embodiment, the shuttle plate may be transported in the second direction DR2 by the shuttle plate driver SPD. Accordingly, the shuttle plate and the first tray TR1 loaded on the shuttle plate may be located in the third area.

Referring to FIGS. 15, 16, and 17, the first tray TR1 may be loaded on a second plate spaced apart from the first plate, while a second tray TR2 different from the first tray TR1 may be gripped (S500). In an embodiment, the first tray TR1 may be loaded on the auxiliary plate APLT by the auxiliary tray shuttle part 40, while the second tray TR2 may be gripped by the tray gripper TP.

As illustrated in FIG. 15, the first auxiliary gripper AP1 may descend to grip the first tray TR1 loaded on the shuttle plate SPLT. After gripping the first tray TR1, the first auxiliary gripper AP1 may rise.

The first auxiliary gripper AP1 may be spaced apart from the auxiliary plate APLT in a plan view. In this process, the second auxiliary gripper AP2 may overlap the auxiliary plate APLT in a plan view. In an embodiment, the second auxiliary gripper AP2 may contact the auxiliary plate APLT.

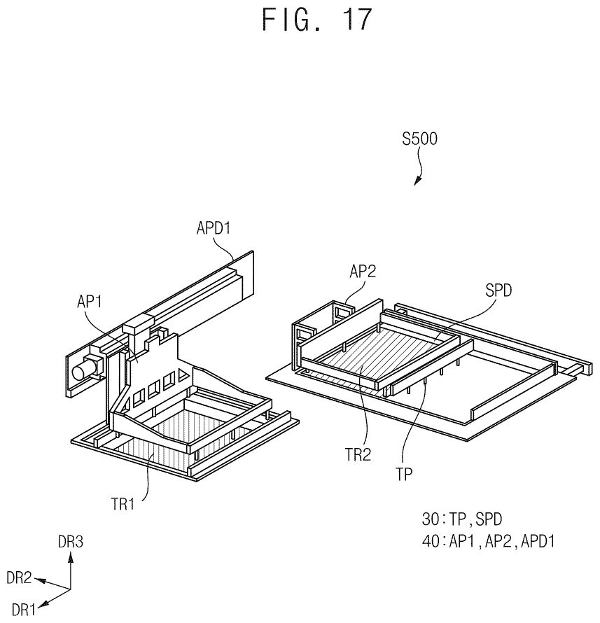

As illustrated in FIG. 16, the first auxiliary gripper AP1 may move in the first direction DR1 while gripping the first tray TR1. In an embodiment, the first auxiliary gripper driver APD1 may move the first auxiliary gripper AP1 in the first direction DR1 such that the first auxiliary gripper AP1 overlaps the auxiliary plate APLT in a plan view.

The second auxiliary gripper AP2 may rise. In addition, the second auxiliary gripper AP2 may move in the opposite direction of the first direction DR1. In an embodiment, the second auxiliary gripper driver (APD2, refer to FIG. 9) may move the second auxiliary gripper AP2 in the opposite direction of the first direction DR1 such that the second auxiliary gripper AP2 overlaps the third area in a plan view.

The tray gripper TP may grip the second tray TR2 among the trays TR raised by the first tray lifting and lowering part 20. The second tray TR2 may be defined as a tray located at the uppermost position among the trays TR excluding the first tray TR1. The tray gripper TP may descend to grip the second tray TR2, and then rise.

To load the second tray TR2 on the shuttle plate SPLT, the shuttle plate driver SPD may transport the shuttle plate SPLT located in the third area to the second area. In other words, the shuttle plate driver SPD may transport the shuttle plate SPLT in the opposite direction of the second direction DR2. When the shuttle plate SPLT is located in the second area, the tray gripper TP may load the second tray TR2 on the shuttle plate SPLT.

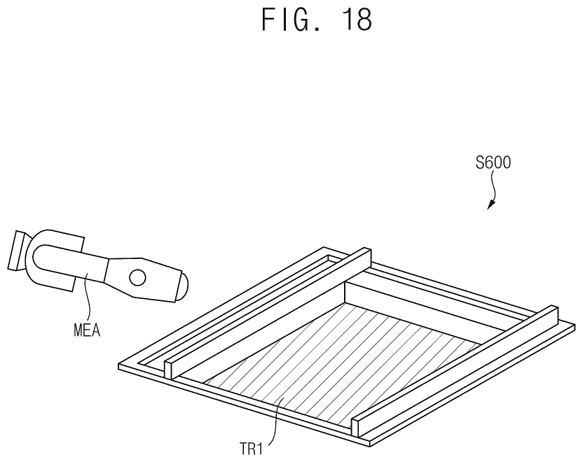

As illustrated in FIG. 17, the shuttle plate SPLT may be transported in the second direction DR2 by the shuttle plate driver SPD. Accordingly, the shuttle plate SPLT and the second tray TR2 loaded on the shuttle plate SPLT may be located in the third area.

The first auxiliary gripper AP1 may descend to load the first tray TR1 on the auxiliary plate APLT. In this process, the first auxiliary gripper AP1 may overlap the auxiliary plate APLT in a plan view. In an embodiment, the first auxiliary gripper AP1 may contact the auxiliary plate APLT.

The second auxiliary gripper AP2 may descend to grip the second tray TR2 loaded on the shuttle plate SPLT. After gripping the second tray TR2, the second auxiliary gripper AP2 may rise. In this process, the second auxiliary gripper AP2 may be spaced apart from the auxiliary plate APLT in a plan view.

As illustrated in FIGS. 15 to 17, while the trays TR are loaded on the auxiliary plate APLT by the auxiliary tray shuttle part 40, the tray shuttle part 30 may prepare the trays TR from which the panel is to be extracted in the next process. In an embodiment, while the trays TR are loaded on the auxiliary plate APLT by the first auxiliary gripper AP1 and the second auxiliary gripper AP2, the tray gripper TP may load the trays TR from which the panel is to be extracted in the next process on the shuttle plate SPLT. Accordingly, since the trays TR from which the panel is to be extracted in the next process can be prepared in advance, the process time can be reduced compared to a case where the panel is extracted while being loaded on the shuttle plate SPLT.

Although not illustrated in FIGS. 15 to 17, the second auxiliary gripper AP2 may move in the first direction DR1 while gripping the second tray TR2. In an embodiment, the second auxiliary gripper driver may transport the second auxiliary gripper AP2 in the first direction DR1 such that the second auxiliary gripper AP2 overlaps the auxiliary plate APLT in a plan view. In addition, the second auxiliary gripper AP2 may move in the opposite direction of the third direction DR3 to load the second tray TR2 on the auxiliary plate APLT.

Gripping the tray TR and loading the tray TR on the auxiliary plate APLT by the first auxiliary gripper AP1 and the second auxiliary gripper AP2 described above with reference to FIGS. 15 to 17 may be repeatedly performed. In embodiments, the first auxiliary gripper AP1 and the second auxiliary gripper AP2 may alternately load the tray TR on the auxiliary plate APLT. When the first auxiliary gripper AP1 loads a tray which is located at (N−1)-th position from the top among the trays TR on the auxiliary plate APLT, the second auxiliary gripper AP2 may load a tray which is located at N-th position from the top among the trays TR on the auxiliary plate APLT. Here, N is a natural number greater than 1. In an embodiment, for example, when the first auxiliary gripper AP1 loads the first tray TR1 on the auxiliary plate APLT, the second auxiliary gripper AP2 may load the second tray TR2 on the auxiliary plate APLT.

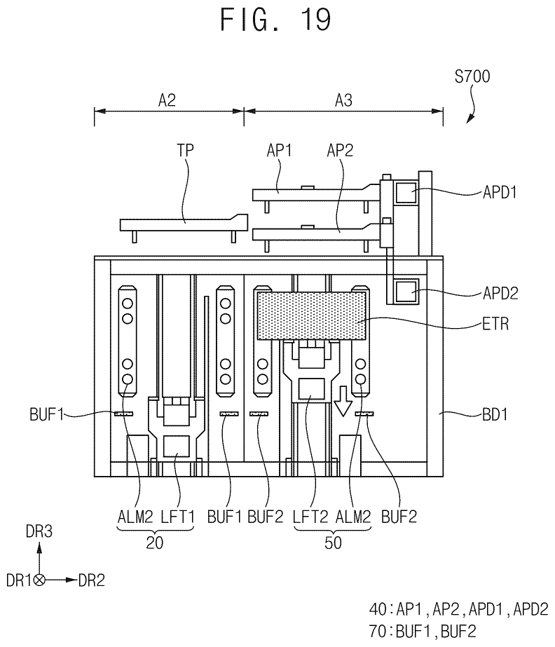

Referring to FIG. 18, the panel may be extracted from the first tray TR1 loaded on the second plate (S600). In an embodiment, the panel may be extracted from the first tray TR1 loaded on the auxiliary plate APLT.

In an embodiment, before the panel is extracted, a visual inspection of the panel may be performed. When the panel is determined to be good (or determined as having not defect) as a result of the visual inspection, the panel may be extracted. In an embodiment, the panel may be extracted from the first tray TR1 loaded on the auxiliary plate APLT by an external apparatus MEA.

Referring to FIGS. 19, 20, and 21, empty trays ETR from which the panel is extracted may be recovered (S700). In other words, the empty trays ETR from which the panel is extracted may be discharged to the outside of the tray loading and unloading apparatus.

Although not illustrated in FIGS. 19, 20, and 21, the empty trays ETR from which the panel is extracted may be gripped by the first auxiliary gripper AP1 or the second auxiliary gripper AP2, and the empty trays ETR may be delivered to the second tray lifting and lowering part 50.

In an embodiment, the second tray lifter LFT2 may raise the second lifter plate (LPLT2, refer to FIG. 6), and the empty trays ETR may be loaded on the second lifter plate. After the empty trays ETR are loaded on the second lifter plate, the first alignment members and the second alignment members ALM2 may align the empty trays ETR.

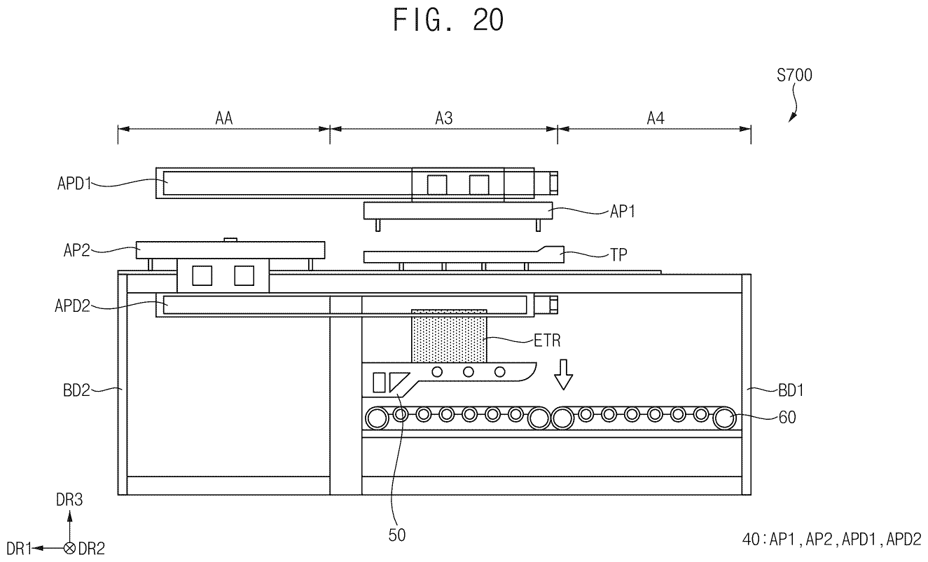

As illustrated in FIGS. 19 and 20, the second tray lifter LFT2 may lower the empty trays ETR loaded on the second lifter plate. In other words, the second tray lifter LFT2 may transport the empty trays ETR in the opposite direction of the third direction DR3. Accordingly, the empty trays ETR may be loaded on the second conveyor belt (CVB2, refer to FIG. 10).

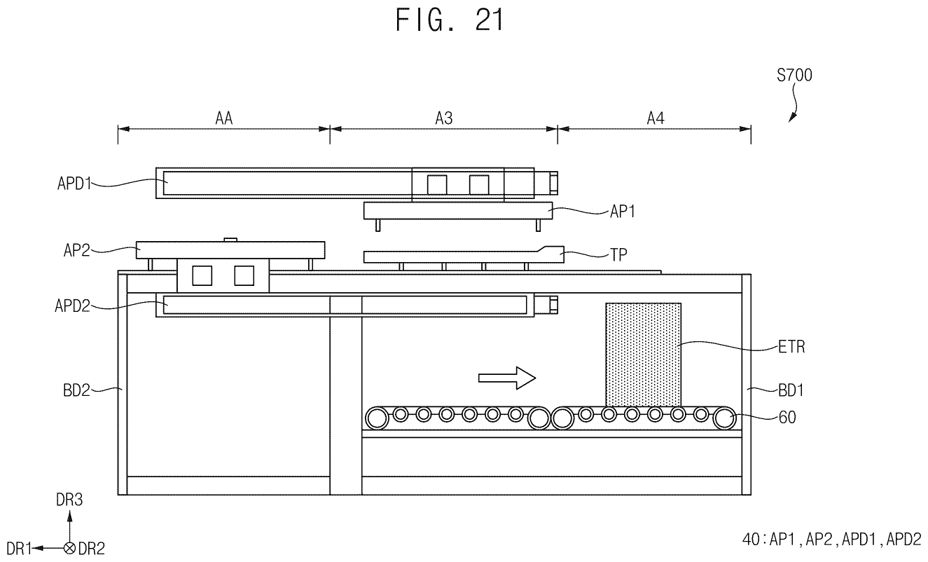

As illustrated in FIG. 21, the tray discharge part 60 may transport the empty trays ETR in the opposite direction of the first direction DR1. In an embodiment, the empty trays ETR may be loaded on the second conveyor belt, and the second conveyor belt may transport the empty trays ETR from the third area A3 to the fourth area A4. In addition, the empty trays ETR may be transported by the second conveyor belt to the outside of the tray loading and unloading apparatus. Accordingly, the empty trays ETR from which the panel is extracted may be recovered.

FIGS. 22 and 23 are views illustrating a method of loading and unloading a tray according to an embodiment of the disclosure.

An embodiment of a method LM′ of loading and unloading a tray described below with reference to FIGS. 22 and 23 may be performed using the tray loading and unloading apparatus 100 described above with reference to FIGS. 1 to 7. In addition, the method LM′ of loading and unloading the tray described below with reference to FIGS. 22 and 23 may be substantially the same as the method LM of loading and unloading the tray described above with reference to FIGS. 9 to 21, except that the method LM′ further includes loading some of the trays on a buffer member. Hereinafter, any repetitive detailed descriptions of the same or like processes as those of the method LM of loading and unloading the tray described above with reference to FIGS. 9 to 21 will be omitted or simplified.

Referring to FIG. 22, the tray gripper TP may sequentially grip each of the trays raised by the first tray lifting and lowering part 20 and may load the trays on the shuttle plate. That is, the tray gripper TP may first grip a tray located at the uppermost position among the trays, and may lastly grip a tray located at the bottommost position (hereinafter, referred to as a final tray FTR) among the trays.

After the trays excluding the final tray FTR are gripped by the tray gripper TP, the first buffer support parts BUF1 may rise toward the final tray FTR. In other words, the first buffer support parts BUF1 may move in the third direction DR3.

Referring to FIG. 23, some of the trays may be loaded on the buffer member. In an embodiment, the final tray FTR among the trays may be loaded on the first buffer support parts BUF1.

The first buffer support parts BUF1 may receive the final tray FTR from the first tray lifting and lowering part 20. The first buffer support parts BUF1 may support the final tray FTR before the final tray FTR is gripped by the tray shuttle part 30. In other words, the final tray FTR may be loaded on the first buffer support parts BUF1 before being gripped by the tray shuttle part 30. After the final tray FTR is loaded on the first buffer support parts BUF1, the first tray lifter LFT1 may lower the first lifter plate.

That is, the first tray lifting and lowering part 20 may deliver the final tray FTR to the first buffer support parts BUF1, and the first tray lifter LFT1 may lower to load the trays to be raised in the next process. In other words, while the tray gripper TP grips the final tray FTR, the first tray lifting and lowering part 20 may prepare the trays to be raised in the next process. In an embodiment, while the tray gripper part TP grips the final tray FTR, the trays to be raised in the next process may be loaded on the first lifter plate (LPLT1, refer to FIG. 7). Accordingly, since the trays to be raised in the next process can be prepared in advance, the process time can be reduced compared to a case where the tray gripper TP grips the final tray FTR while the final tray FTR is loaded on the first lifter plate.

In an embodiment, although not illustrated in FIGS. 22 and 23, in the recovering the empty trays from which the panel is extracted, the second buffer support parts BUF2 may rise towards the upper portion of the first body part BD1. To reduce the process time, while the second tray lifter LFT2 descends in advance to load the empty trays on the second conveyor belt, the second buffer support parts BUF2 may receive a residual empty tray from the auxiliary tray shuttle part 40 or from the tray shuttle part. In such an embodiment, the second buffer support parts BUF2 may support the residual empty tray before the residual empty tray is delivered to the second tray lifting and lowering part 50. Subsequently, the second tray lifter LFT2 may rise and receive the residual empty tray from the second buffer support parts BUF2.

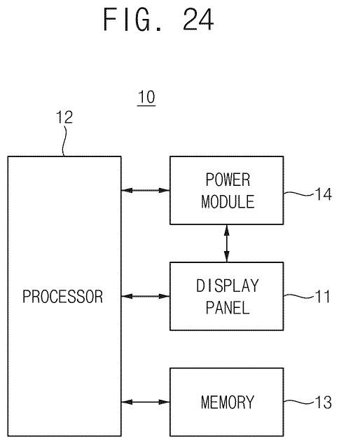

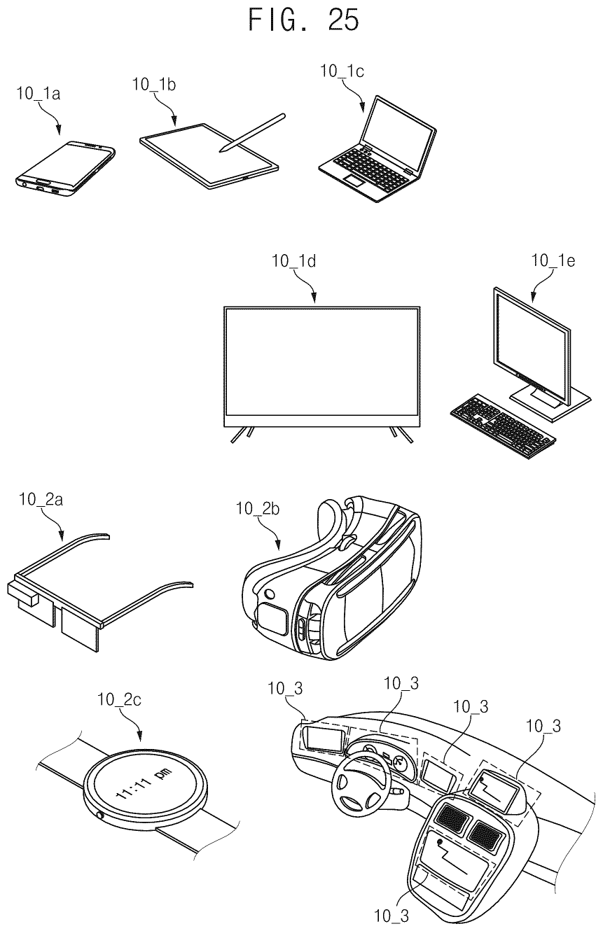

FIG. 24 is a block diagram of an electronic device according to an embodiment of the present disclosure.

Referring to FIG. 24, an electronic device 10 according to an embodiment may include a display panel 11, a processor 12, a memory 13, and a power module 14. The display device according to an embodiment may be applied to a variety of electronic devices. The electronic device 10 according to an embodiment may include the display device described above, and may further include modules or devices having other additional functions in addition to the display device.

The processor 12 may include at least one of a central processing unit (“CPU”), an application processor (“AP”), a graphic processing unit (“GPU”), a communication processor (“CP”), an image signal processor (“ISP”), and a controller.

The memory 13 may store data information required for operation of the processor 12 or the display panel 11. When the processor 12 executes an application stored in the memory 13, an image data signal and/or a input control signal may be transmitted to the display panel 11, and the display panel 11 may process the received signals and may output image information through a display screen.

The power module 14 may include a power supply module, such as a power adapter or a battery device, etc., and a power conversion module that converts power supplied by the power supply module to generate the power required for operation of the electronic device 10. That is, the power module 14 may provide power to the display device according to the embodiments described above.

At least one of the components of the electronic device 10 described above may be included in the display device according to the embodiments described above. In addition, some of the individual modules that are functionally included in one module may be included in the display device and others may be provided separately from the display device. For example, the display device may include the display panel 11, and the processor 12, the memory 13, and the power module 14 may be provided in the form of other devices in the electronic device 10 other than the display device.

FIG. 25 is a schematic diagram of an electronic device according to various embodiments.

Referring to FIG. 25, various electronic devices to which a display device according to the embodiments is applied may include image display electronic devices such as a smartphones 10_1a, a tablet PC 10_1b, a laptop 10_1c, a television 10_1d, a desk monitor 10_1e, etc., wearable electronic devices including display panels such as a smart glasses 10_2a, a head-mounted display 10_2b, and a smart watch 10_2c, etc., and vehicle electronic devices (10_3) including display panels such as a CID (center information display) which may be disposed on a instrument panel, a center fascia, and a dashboard of an automobile and a room mirror display, etc.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A method of loading and unloading a tray, the method comprising:
transporting trays, on which a panel is disposed;
gripping a first tray among the trays and loading the first tray on a first plate;
gripping the first tray loaded on the first plate and loading the first tray on a second plate spaced apart from the first plate, while simultaneously gripping a second tray different from the first tray among the trays;
extracting the panel from the first tray loaded on the second plate; and
recovering empty trays, from which the panel is extracted.

2. The method of claim 1, further comprising:
loading the second tray on the second plate after the extracting the panel from the first tray; and
extracting the panel from the second tray loaded on the second plate.

3. The method of claim 2,
wherein the first tray is loaded on the second plate by a first gripper, and
wherein the second tray is loaded on the second plate by a second gripper different from the first gripper.

4. The method of claim 3, wherein the first gripper and the second gripper alternately load the trays on the second plate.

5. The method of claim 1, further comprising:
loading at least one of the trays on a buffer member after the transporting the trays.

6. The method of claim 5, wherein a tray located at a bottommost position among the trays is loaded on the buffer member.

7. The method of claim 5, wherein the transporting the trays includes:
loading the trays on a lifting and lowering member, and
raising the trays by the lifting and lowering member.

8. The method of claim 7, wherein the buffer member receives the at least one of the trays from the lifting and lowering member.

9. The method of claim 8, further comprising:
lowering the lifting and lowering member after the loading the at least one of the trays on the buffer member.

10. A tray loading and unloading apparatus, the apparatus comprising:
a tray input part which transports trays, on which a panel is disposed, from a first area to a second area adjacent to the first area in a first direction;
a first tray lifting and lowering part overlapping the second area, wherein the first tray lifting and lower part raises the trays transported by the tray input part;
a tray shuttle part which grips each of the trays from the first tray lifting and lowering part, loads each of the trays on a shuttle plate, and transports the shuttle plate in a second direction intersecting the first direction;
an auxiliary tray shuttle part which grips each of the trays loaded on the shuttle plate and loads each of the trays on an auxiliary plate spaced apart from the shuttle plate;
a second tray lifting and lowering part overlapping a third area adjacent to the second area in the second direction, wherein the second tray lifting and lowering part lowers an empty tray, from which the panel is extracted; and
a tray discharge part which transports the empty tray from the third area to an outside of the apparatus.

11. The apparatus of claim 10, wherein the panel is extracted while being loaded on the auxiliary plate.

12. The apparatus of claim 10, wherein the auxiliary tray shuttle part includes:
an auxiliary gripper which grips each of the trays loaded on the shuttle plate; and
an auxiliary gripper driver which transports the auxiliary gripper toward the auxiliary plate.

13. The apparatus of claim 12,
wherein the auxiliary gripper includes a first auxiliary gripper and a second auxiliary gripper which are driven independently of each other, and
wherein the auxiliary gripper driver includes a first auxiliary gripper driver which transports the first auxiliary gripper and a second auxiliary gripper driver which transports the second auxiliary gripper.

14. The apparatus of claim 13, wherein when the first auxiliary gripper overlaps the auxiliary plate in a plan view, the second auxiliary gripper is spaced apart from the auxiliary plate in the plan view.

15. The apparatus of claim 13, wherein the first auxiliary gripper and the second auxiliary gripper alternately load the trays on the auxiliary plate.

16. The apparatus of claim 10, further comprising:
a tray buffer part on which at least one of the trays are loaded.

17. The apparatus of claim 16, wherein the tray buffer part receives the least one of the trays from the first tray lifting and lowering part.

18. The apparatus of claim 16, wherein the tray buffer part includes buffer support parts which contact the at least one of the trays.

19. The apparatus of claim 18, wherein the buffer support parts include first buffer support parts disposed in the second area and second buffer support parts disposed in the third area.

20. An electronic device comprising:
a display device including a display panel loaded by a tray loading and unloading apparatus; and
a processor which transmits an image data signal and an input control signal to the display device,
wherein the tray loading and unloading apparatus comprises:
a tray input part which transports trays, on which the display panel is disposed, from a first area to a second area adjacent to the first area in a first direction;
a first tray lifting and lowering part overlapping the second area, wherein the first tray lifting and lower part raises the trays transported by the tray input part;
a tray shuttle part which grips each of the trays from the first tray lifting and lowering part, loads each of the trays on a shuttle plate, and transports the shuttle plate in a second direction intersecting the first direction;
an auxiliary tray shuttle part which grips each of the trays loaded on the shuttle plate and loads each of the trays on an auxiliary plate spaced apart from the shuttle plate;
a second tray lifting and lowering part overlapping a third area adjacent to the second area in the second direction, wherein the second tray lifting and lowering part lowers an empty tray, from which the display panel is extracted; and
a tray discharge part which transports the empty tray from the third area to an outside of the apparatus.
